(19) United States
(12) Patent Application Publication
(10) Pub. No.: US 2024/0119199 A1
(43) Pub. Date: Apr. 11, 2024

(54) METHOD AND SYSTEM FOR GENERATING TIME-EFFICIENT SYNTHETIC NON-DESTRUCTIVE TESTING DATA

(71) Applicant: INDIAN INSTITUTE OF TECHNOLOGY MADRAS (IIT MADRAS), Chennai, Tamil Nadu (IN)

(72) Inventors: Krishnan BALASUBRAMANIAN, Chennai, Tamil Nadu (IN); Thulsiram GANTALA, Telangana (IN)

(21) Appl. No.: 18/265,701

(22) PCT Filed: Feb. 14, 2022
(86) PCT No.: PCT/IN2022/050125

§ 371 Date: Jun. 7, 2023

(30) Foreign Application Priority Data
Feb. 19, 2021 (IN) 202141007067

(51) Int. Cl. G06F 30/23; G06F 30/27

(52) U.S. Cl. CPC G06F 30/23; G06F 30/27

(57) ABSTRACT

Disclosed herein is a method and system for generating synthetic non-destructive testing dataset. The system receives non-destructive testing datasets related to real-time experimentation of non-destructive testing as input. The testing datasets include dimensions of defective samples, expected defect morphologies, defect probabilities, the sensitivity of instruments, observation from experimental datasets, noise from instrumentation. The system performs numerical analysis on the received one or more non-destructive testing datasets containing one or more flawed geometrical features for generating one or more non-destructive training datasets by using a numerical simulation model. The system further trains a Deep Convolutional Generative Adversarial Network (DCGAN) by using the generated one or more non-destructive training datasets with flaw geometrical features. The system receives a plurality of random number input vectors iteratively at the trained DCGAN and generates a synthetic non-destructive dataset for each of the plurality of received random number input vectors using the trained DCGAN.

### TECHNICAL FIELD

The present subject matter is related to the generation of non-destructive testing data in general and, more particularly, but not exclusively related to method and system for generating a large volume of non-destructive training datasets by using artificial intelligence (AI).

### BACKGROUND

Non-destructive testing (NDT) is the process of inspecting, testing, or evaluating materials, components, or assemblies for characteristics differences or welding defects, discontinuities, etc., without causing damage to the serviceability of such materials components or assemblies. NDT is also commonly known as non-destructive examination (NDE), non-destructive inspection (NDI), and non-destructive evaluation (NDE). NDT is used across different industries such as mechanical engineering, electrical engineering, systems engineering, civil engineering, aerospace engineering, automotive, power, marine, oil, gas, etc. NDT provides an accurate inspection method by enabling repeatable tests and is cost-effective as NDT eliminates the need to replace test objects. NDT is used in manufacturing, fabrication, and in-service inspections to ensure product integrity and reliability, control manufacturing processes, lower production costs, and maintain a uniform quality level. There are different NDT methods to examine a wide variety of articles for integrity, composition, or condition with no alteration of the article undergoing examination. Such methods include but not limited to Acoustic Emission Testing (AE), Electromagnetic Testing (ET), Laser Testing Methods (LM), Leak Testing (LT), Magnetic Flux Leakage (MFL), Liquid Penetrant Testing (PT), Magnetic Particle Testing (MT), Radiographic Testing (RT), Thermal/Infrared Testing (IR), Ultrasonic Testing (UT), Vibration Analysis (VA), etc.

Further, with the advent of different artificial intelligence (AI) and machine learning (ML) techniques, researchers have used such techniques for defect detection and classification in the NDT domain Such AI and ML techniques also require sufficient training data in order to efficiently detect and classify defects for a wide variety of test input in real time. However, the challenge with such AI and ML techniques is the limited availability of representative data in the NDT domain. Also, data augmentation from experimentation and existing techniques is a computationally time-consuming and costly process, and the augmented data also lacks in having a variety of flaw characteristics. Therefore, the implementation of AI and ML techniques based on limited representative data fails to provide accurate detection and classification of defects in NDT/NDE.

The information disclosed in this background of the disclosure section is only for enhancement of understanding of the general background of the invention and should not be taken as an acknowledgement or any form of suggestion that this information forms the prior art already known to a person skilled in the art.

### SUMMARY

One or more shortcomings of the prior art are overcome, and additional advantages are provided through the present disclosure. Additional features and advantages are realized through the techniques of the present disclosure. Other embodiments and aspects of the disclosure are described in detail herein and are considered a part of the claimed disclosure.

Accordingly, the present disclosure relates to a method of generating synthetic non-destructive testing dataset. The method includes receiving one or more non-destructive testing datasets related to real-time experimentation of non-destructive testing, wherein the testing datasets include dimensions of defective samples, expected defect morphologies, defect probabilities, the sensitivity of instruments, observation from experimental datasets, and noise from instrumentation. The method comprises performing numerical analysis on the received one or more non-destructive testing datasets containing one or more flawed geometrical features for generating one or more non-destructive training datasets by using a numerical simulation model and training a Deep Convolutional Generative Adversarial Network (DCGAN) by using the generated one or more non-destructive training datasets with flawed geometrical features. The method further comprises receiving a plurality of random number input vectors iteratively at the trained DCGAN and generating, by the trained DCGAN, a synthetic non-destructive dataset for each of the plurality of received random number input vectors.

Further, the disclosure relates to a system for generating synthetic non-destructive testing dataset. The system comprises a processor and a memory communicatively coupled with the processor, wherein the memory stores processor-executable instructions, which, on execution, cause the processor to receive one or more non-destructive testing datasets related to real-time experimentation of non-destructive testing. The testing datasets include dimensions of defective samples, expected defect morphologies, defect probabilities, the sensitivity of instruments, observation from experimental datasets, and noise from instrumentation. The processor is configured to perform numerical analysis on the received one or more non-destructive testing datasets containing one or more flawed geometrical features for generating one or more non-destructive training datasets by using a numerical simulation model. The processor further trains a Deep Convolutional Generative Adversarial Network (DCGAN) by using the generated one or more non-destructive training datasets with flawed geometrical features. The processor receives a plurality of random number input vectors iteratively at the trained DCGAN and generates a synthetic non-destructive dataset for each of the plurality of received random number input vectors by using the trained DCGAN.

The foregoing summary is illustrative only and is not intended to be in anyway limiting. In addition to the illustrative aspects, embodiments, and features described above, further aspects, embodiments, and features will become apparent by reference to the drawings and the following detailed description.

### BRIEF DESCRIPTION OF DRAWINGS

The accompanying drawings, which are incorporated in and constitute a part of this disclosure, illustrate exemplary embodiments and, together with the description, serve to explain the disclosed principles. In the figures, the left-most digit(s) of a reference number identifies the figure in which the reference number first appears. The same numbers are used throughout the figures to reference like features and components. Some embodiments of device or system and/or methods in accordance with embodiments of the present subject matter are now described, by way of example only, and with reference to the accompanying figures, in which:

FIG. 1 illustrates an exemplary architecture of a proposed system to generate NDT datasets in accordance with some embodiments of the present disclosure;

FIG. 2 illustrates an exemplary block diagram of a system for generating NDT datasets in accordance with an embodiment of the present disclosure;

FIG. 3 illustrates an exemplary diagram of Deep Convolutional Generative Adversarial Network (DCGAN) used in the proposed system in accordance with some embodiments of the present disclosure;

FIG. 4 illustrates a flowchart showing a method of generating NDT datasets in accordance with some embodiments of the present disclosure;

FIG. 5 illustrates a flowchart showing a method of determining a numerical simulation model for generating NDT datasets in accordance with some embodiments of the present disclosure;

FIG. 6 illustrates an exemplary illustration of data flow for automated defect recognition in accordance with an embodiment of the present disclosure;

FIG. 7 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether or not such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however, that it is not intended to limit the disclosure to the particular forms disclosed, but on the contrary, the disclosure is to cover all modifications, equivalents, and alternatives falling within the spirit and the scope of the disclosure.

The terms “comprises”, “comprising”, “include(s)”, or any other variations thereof, are intended to cover a non-exclusive inclusion, such that a setup, device or method that comprises a list of components or steps does not include only those components or steps but may include other components or steps not expressly listed or inherent to such setup or device or method. In other words, one or more elements in a device or system or apparatus proceeded by “comprises . . . a” does not, without more constraints, preclude the existence of other elements or additional elements in the device or system or apparatus.

Embodiments of the present disclosure relate to a method and system for generating synthetic non-destructive training datasets. The system receives one or more non-destructive testing datasets related to real-time experimentation of non-destructive testing. The testing datasets include dimensions of defective samples, expected defect morphologies, defect probabilities, the sensitivity of instruments, observation from experimental datasets, and noise from instrumentation. The system performs numerical analysis on the received one or more non-destructive testing datasets containing one or more flawed geometrical features for generating one or more non-destructive training datasets by using a numerical simulation model. In the process of generating one or more non-destructive training datasets, the system determines a CAD model representing the actual physical defect sample based on the received geometrical features. The system further determines one or more critical statistical distribution parameters using probability distribution function, wherein the one or more critical statistical distribution parameters are randomized with respect to the CAD model in order to generate a plurality of CAD datasets. The system further uses the CAD datasets to generate one or more non-destructive training datasets. The system trains a Deep Convolutional Generative Adversarial Network (DCGAN) by using the generated one or more non-destructive training datasets with flawed geometrical features. The system further receives a plurality of random number input vectors iteratively at the trained DCGAN and generates a synthetic non-destructive dataset for each of the plurality of received random number input vectors by using the trained DCGAN.

In the following detailed description of the embodiments of the disclosure, reference is made to the accompanying drawings that form a part hereof and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

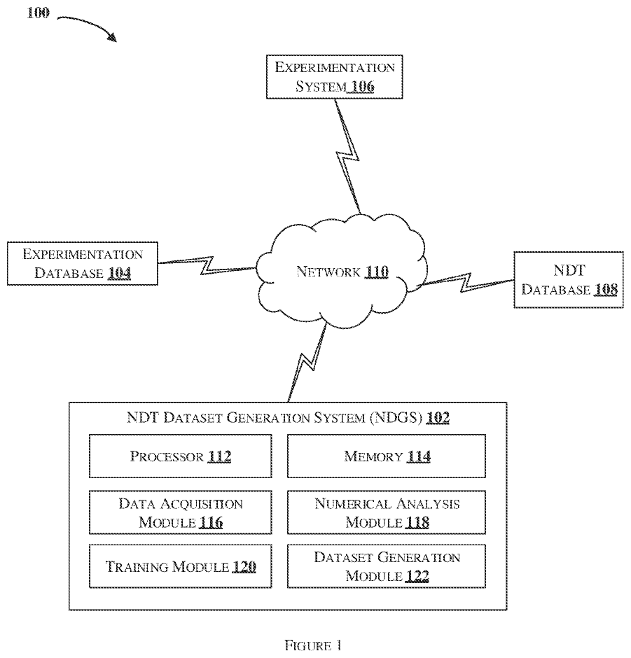

FIG. 1 illustrates an exemplary architecture of a proposed system (100) for generating non-destructive training datasets in accordance with some embodiments of the present disclosure.

As shown in FIG. 1, the exemplary system (100) comprises one or more components configured for generating non-destructive training dataset. In one embodiment, the system (100) comprises a system for generating non-destructive training dataset (hereinafter referred to as NDGS) (102), an experimentation database (104), an experimentation system (106), and an NDT database (108) communicatively coupled via a communication network (110). The communication network (110) may include, without limitation, a direct interconnection, LAN (local area network), WAN (wide area network), wireless network, point-to-point network, or another configuration. One of the most common types of network in current use is a TCP/IP (Transfer Control Protocol and Internet Protocol) network for communication between database client and database server. Other common Internet protocols used for such communication include HTTPS, FTP, AFS, WAP, other secure communication protocols, etc.

The experimentation database (104) is capable of storing plurality of information related to real-time experiments of non-destructive testing in the respective dataset. The experimentation database (104) stores information related to one or more samples used in the real-time experiments, wherein the information includes length, thickness, defect information, etc., related to one or more samples. The experimentation database (104) further stores a plurality of information related to one or more parameters influencing the real-time experiment. Such parameters include but are not limited to defect morphologies, defect probabilities, instrument sensitivity, noise from the instrument, etc. The experimentation database (104) also stores observations of NDT experts received either manually or via some suitable digital interfaces. In one embodiment, the experimentation database (104) may be integrated within the NDGS (102). In another embodiment, experimentation database (104) may be configured, for example, as a standalone datastore. In yet another example, experimentation database (104) may be configured in a cloud environment. The experimentation database (104) may be, for example, one of data tables, flat files, spreadsheet, or any document comprising one or more data elements. The NDGS (102) may retrieve any information related to real-time experiments from the experimentation database (104) for generating one or more non-destructive training datasets.

The experimentation system (106) may be a system that aids in performing real-time experiments on one or more physical samples to identify flaws within the physical samples. In an example, the experimentation system (106) may be configured with an FMC-TFM experiment setup that comprises an instrument for Phased Array Ultrasonic Testing (PAUT). The PAUT is an advanced non-destructive examination technique that utilizes a set of ultrasonic testing (UT) probes made up of numerous small elements, each of which is pulsed individually with computer-calculated timing. The PAUT technique can be used to inspect more complex geometries that are difficult and much slower to inspect with single probes. Further, the PAUT can be used to inspect almost any material where traditional UT methods have been utilized and are often used for weld inspections and crack detection. The experimentation system (106) may further be integrated with the NDGS (102) to provide real-time experiment information as input to the NDGS (102), wherein the NDGS (102) generates a plurality of synthetic non-destructive testing datasets based on the received input. The experimentation system (106) stores the real-time experiment information in the experimentation database (104) for future reference.

The NDT database (108) is capable of storing plurality of operational data of the NDGS (102) in the respective dataset. The NDT database (108) stores information related to computer aided design (CAD) geometry of one or more physical samples, one or more critical flaw parameters, validation information for numerical simulation method, over which the NDGS (102) can perform operations to generate a plurality of synthetic non-destructive testing datasets. The NDT database (108) further stores validated numerical simulation model, operating information of numerical methods for determining such model, the output of randomized critical distribution parameters, full matrix capture data, reconstructed training datasets, etc. The NDT database (108) stores a plurality of non-destructive training datasets as generated by using the numerical simulation model for training an artificial intelligence model. The NDT database (108) can further store a plurality of defect patterns, correlation between sample dimensions and defect patterns, and other training information as imparted via the training process. In one embodiment, the NDT database (108) may be integrated within the NDGS (102). In another embodiment, the NDT database (108) may be configured, for example, as a standalone datastore. In yet another example, the NDT database (108) may be configured in a cloud environment. The NDT database (108) may be, for example, one of data tables, flat files, spreadsheet, or any document comprising one or more data elements.

The NDGS (102) may provide one or more functionalities to generate the synthetic NDT datasets. In one embodiment, the NDGS (102) may be configured within a computing device having a large storage capacity, with one or more microprocessors and high-speed network connections. In one example, the NDGS (102) may be a software or an integrated web application, and the components of the NDGS (102) may support one or more functions or services related to synthetic non-destructive testing dataset generation. The NDGS (102) may be configured in a cloud environment or as a standalone system. In one embodiment, the NDGS (102) comprises a processor (112), and a memory (114) coupled to the processor (112). The processor (112) and the memory (114) are communicatively coupled to the experimentation database (104), the experimentation system (106), and the NDT database (108) via the communication network (110). The memory (114) may be a removable or non-removable component of a computing device configured to store one or more instructions to be executed by one or more processors. In one embodiment, the memory may comprise a deep convolutional generative adversarial network for determining non-destructive testing datasets in a time-efficient manner In an example, the processor (112) can be one of general purpose central processing unit (CPU), graphical processing unit (GPU), application specific processors, and logic devices, as well as any other type of processing device, combinations, or variations thereof.

The NDGS (102) further comprises one or more modules configured to enable the generation of a plurality of synthetic non-destructive testing datasets. In one embodiment, one or more modules include a data acquisition module (116), a numerical analysis module (118), a training module (120), and a dataset generation module (122). The NDGS (102) is configured to perform numerical analysis on non-destructive testing datasets to generate one or more non-destructive training datasets. The NDGS (102) also validates a numerical simulation model used in the numerical analysis. The NDGS (102) further facilitates training a Deep Convolution Generative Adversarial Network (DCGAN) by using the one or more non-destructive training datasets as input. Therefore, the NDGS (102) provides a testing datasets generation system performing numerical analysis of limited real-time experiment information for generating NDT training datasets and training an artificial intelligence model by using the NDT training datasets for generating a large volume of NDT testing datasets with different variety of flaws in very less time.

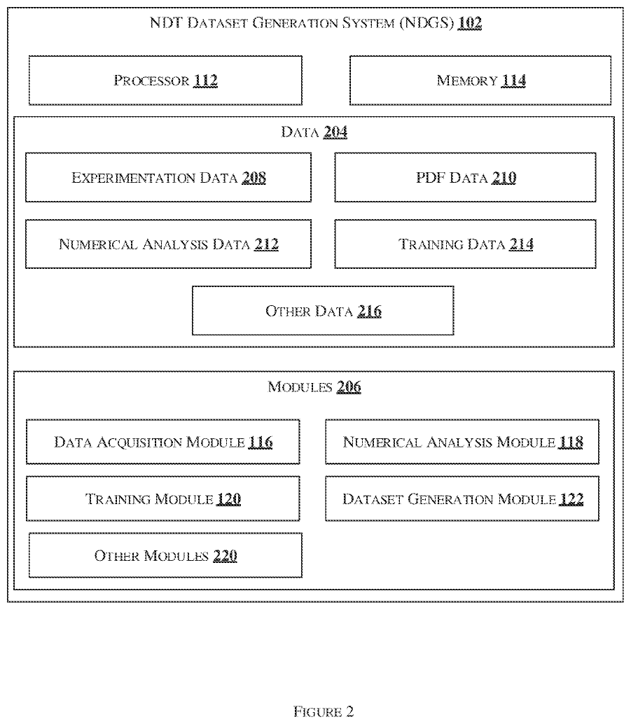

The NDGS (102) may be configured in a cloud environment. In one embodiment, the NDGS (102) may be configured as a standalone system. In another embodiment, the NDGS (102) may be a typical dataset generation system as illustrated in FIG. 2. The NDGS (102) further includes data (204) and modules (206). In one implementation, the data (204) can be stored within the memory (114). In one example, the data (204) may include experimentation data (208), PDF (Probability Distribution Function) data (210), numerical analysis data (212), training data (214), and other data (216). In one embodiment, the data (204) can be stored in the memory (114) in the form of various data structures. Additionally, the aforementioned data can be organized using data models, such as relational or hierarchical data models. The other data (216) may also be referred to as a reference repository for storing recommended implementation approaches as reference data. The other data (216) may also store data, including temporary data, temporary files, intermediate training data, validation data, etc., as generated by the modules (206) for performing the various functions of the NDGS (102).

The modules (206) may include, for example, the data acquisition module (116), the numerical analysis module (118), the training module (120), and the dataset generation module (122). The modules (206) may also comprise other modules (220) to perform various miscellaneous functionalities of the NDGS (102). It will be appreciated that such aforementioned modules may be represented as a single module or a combination of different modules. The modules (206) may be implemented in the form of software performed by the processor, hardware and/or firmware.

The data acquisition module (116) receives one or more non-destructive testing datasets related to real-time experiment of non-destructive testing of one or more physical samples from the experimentation database (104), wherein the experimentation database (104) stores the testing datasets with respect to the real-time non-destructive testing of physical samples as received from one or more systems conducting such experiment over the time. The received non-destructive testing dataset contains a variety of information with respect to the non-destructive testing of the one or more physical samples. The information related to such non-destructive testing includes but is not limited to dimensions of defective samples, expected defect morphologies, defect probabilities, sensitivity of instruments, observation from experimental datasets, noise from instrumentation, etc. Further, the information related to one or more samples used in real-time experiments includes length, thickness, defect information, etc., related to the one or more physical samples. The information related to the real-time experimentation of non-destructive testing can also include material property, a plurality of flawed geometry features, nature of occurring locations of such flaw within the one or more physical samples, etc. In an example, a flaw can be a weld defect such as porosity, slag, etc. The data acquisition module (116) can also receive such information of real-time non-destructive testing from the experimentation system (106) over the communication network (110). The data acquisition module (116) stores the information related to the real-time experiment of non-destructive testing as the experimentation data (208) in the NDT database (108).

In one embodiment, the numerical analysis module (118) determines a numerical simulation model based on the information as acquired by the data acquisition module (116). In one embodiment, the numerical analysis module (126) retrieves geometrical information of one or more representative defective samples such as geometrical dimension, flaw information, material property, etc., from the experimentation data (208) as stored by the data acquisition module (116). The numerical analysis module (118) determines a CAD model representing one or more actual physical defective samples based on the retrieved geometrical information. The CAD aids in creation, modification, analysis, or optimization of a design of the defective samples. The CAD model also aids in visualizing the properties like height, width, distance, material, color, etc., before the CAD model is used for further processing. The CAD model can be of two-dimensional (2D) and three-dimensional (3D), however for the sake of brevity, 2D CAD model is used in the present invention instead of 3D CAD model as 3D CAD model is computationally expensive, and the variation observed between 2D CAD model simulation and 3D CAD model simulation is nominal. The CAD model can be generated by integrating the NDGS (102) one of the plurality of available computer-based tools for CAD.

Upon determining the CAD model, the numerical analysis module (118) determines one or more critical statistical distribution parameters using probability distribution function (PDF) on plurality of factors influencing the real-time experiment such as expected defect morphologies, defect probabilities, the sensitivity of instruments, etc. The PDF is a mathematical method that determines probabilities of different possible outcomes for an experiment. In an example, the critical statistical distribution parameters can include but are not limited to flaw shape, flaw size, flaw orientation, etc. The numerical analysis module (118) stores the one or more critical statistical distribution parameters as PDF data (210) in the NDT database (108). The numerical analysis module (118) further randomizes the critical statistical distribution parameters in order to generate a plurality of artificial flaw patterns. The numerical analysis module (118) determines a plurality of CAD datasets by inducing one or more flaw patterns into the determined CAD model. Therefore, the different CAD datasets with artificial flaw patterns represent different scenarios of possible defects in the physical samples. Further, the numerical analysis module (118) performs physics based numerical analysis for each of the determined CAD datasets by using one of Finite Element Analysis (PEA), Finite Difference Method (FDM), Finite Volume Method (FVM), etc.

In an example, FEA can be used to determine the numerical simulation model, wherein the numerical simulation model can be a Finite Element (FE) simulation model. In order to perform the FEA, a Finite Element Method (FEM) is adapted, wherein the FEM is used for numerically solving differential equations arising in engineering and mathematical modeling. A series of FE simulations are used to create Full Matrix Capture (FMC) data for artificially introducing different defects, and multi-mode TFM imaging is further used to generate the fully focused images. There are different ultrasonic techniques for inspecting the component. However, the full matrix capture (FMC) and total focusing method (TFM) are technically advanced methods compared to other ultrasonic methods due to generating a fully focused high-resolution digital image.

The FMC method is used to acquire raw A-scans (Amplitude Scan) to form a matrix by using a transmission-reception of a phased array transducer element. In an example, a phased array probe has N elements in an array. One of the elements transmits the ultrasonic signal into a medium, and reflected signal is received by all available probe elements. Such process continues in the sequence to create a matrix that is having a size of N×N×Time, wherein Time is the total time taken for ultrasonic waves to travel a round trip. The TFM technique is a post-processing technique used to construct an image by virtually focusing every point in the region of inspection (ROI). In the TFM, time of flight (TOF) is computed for each grid point between the transducer and receiver positions. The TFM intensity map consisting of intensity values is created for each grid point within ROI. Such intensity map is calculated using a delay and summation of A-scan signals amplitude based on the TOF.

The numerical analysis module (118) reconstructs a non-destructive training dataset for each of the CAD datasets based on the physics based numerical analysis. The reconstructed non-destructive training datasets are also contained with a different variety of flaws that are induced during the preparation of the plurality of CAD datasets. The numerical analysis module (118) further communicates with the experimentation system (106) in order to retrieve a non-destructive training dataset, wherein the experimentation system (106) obtains the non-destructive testing dataset by performing physical experiments of the physical sample having a similar kind of defect as induced into the particular CAD dataset. Upon retrieving the non-destructive testing dataset, the numerical analysis module (118) compares the reconstructed non-destructive training dataset with the retrieved non-destructive testing dataset for verifying a desired result. In case the desired result is not achieved, the numerical analysis module (118) modifies the numerical simulation model by tweaking one or more boundary conditions and respective techniques for physics based numerical analysis until the desired results are obtained. The numerical analysis module (118) stores information related to CAD model, the CAD datasets, information of the validated numerical simulation model as the numerical analysis data (212) in the NDT database (108).

In another embodiment, upon validating the appropriate numerical simulation model, the numerical analysis module (118) retrieves geometrical information of one or more representative defective samples such as geometrical dimension, flaw information, material property, etc., from the experimentation data (208). The numerical analysis module (118) also retrieves information of the validated numerical simulation model from the numerical analysis data (212) of the NDT database (108). The numerical analysis module (118) determines a plurality of CAD datasets by inducing one or more flaw patterns into the determined CAD model that represents one or more actual physical defective samples. The numerical analysis module (118) further reconstructs a non-destructive training dataset for each of the CAD datasets based on the physics based numerical analysis. Thus, the numerical analysis module (118) generates a count of non-destructive training datasets similar to the count of the plurality of CAD datasets. The numerical analysis module (118) further stores the generated non-destructive training datasets as the training data (214) in the NDT database (108).

In one embodiment, the training module (120) retrieves the non-destructive training datasets as stored in the training data (214) and iteratively feeds each of the non-destructive training datasets to the DCGAN in order to train the DCGAN with a variety of input datasets having different types of flaws.

The DCGAN is an extension of the GAN (Generative Adversarial Network) architecture for using deep convolutional neural networks for both generator and discriminator models of the GAN and configurations for the models and training that result in the stable training of a generator model. The DCGAN explicitly uses convolutional and convolutional-transpose layers in the discriminator and generator, respectively. The generator aims to generate a synthetic non-destructive testing dataset close to the non-destructive testing dataset of the real-time experiment by fooling the discriminator. The discriminator seeks to discriminate between the synthetic non-destructive testing dataset and the non-destructive testing dataset of the real-time experiment. The non-destructive testing datasets of the real-time experiment are drawn from a pool of non-destructive testing datasets constructed based on physics based numerical analysis, and the generator generates fake datasets. The generator and the discriminator are trained in an adversarial manner by using a backpropagation technique, wherein such technique enables in generating near-real-time non-destructive testing dataset as output through mutual optimization of one or more hyperparameters. The one or more hyperparameters are the variables that determine the network structure, i.e., number of hidden units and one or more variables that determine how the network is trained, i.e., learning rate. The hyperparameters are set before training or before optimizing weights and bias. The generator and the discriminator are trained in an adversarial manner to generate non-destructive testing datasets by imitating real sample distribution close to real dataset distribution. Once the generator is trained, the DCGAN system learns the flaws probability distribution from input numerical analysis based non-destructive training datasets.

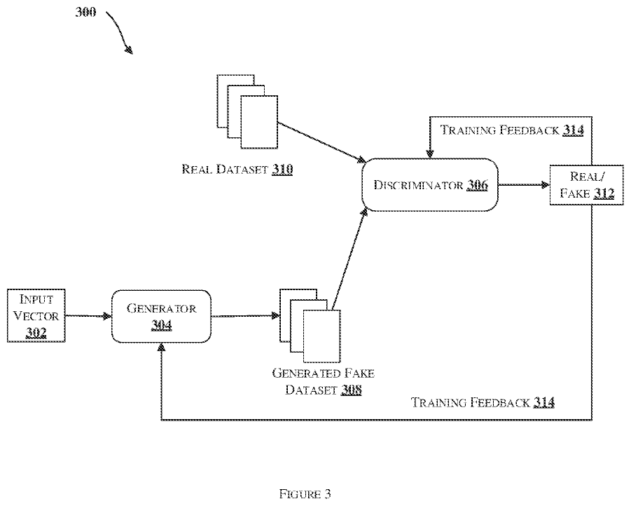

As explained in FIG. 3, the generator (304) generates a fake dataset (308), wherein the discriminator (306) discriminates between the generated fake dataset (308) and the real dataset (310). The generator (304) takes a randomly generated vector (302) as input data and feedback (314) from the discriminator (306) and generates a new fake dataset (308) that are as close to the real dataset (310) as possible. The discriminator (306) uses the output of the generator (304) as training data. The generator (304) gets feedback from the discriminator (306). The discriminator (306) also learns from the feedback of discrimination. With each training iteration of the generator and the discriminator, the networks become stronger in the process of backpropagation. The generator (304) continues creating new datasets and refining the respective process until the discriminator (306) can no longer identify the difference between the generated dataset and the real dataset.

Therefore, the DCGAN is trained to generate one or more synthetic non-destructive testing datasets that are as realistic as the non-destructive testing datasets used in real-time experimentation. Upon completing the training process, the trained DCGAN generates one or more synthetic non-destructive testing datasets in significantly less time than the time taken to generate the non-destructive testing datasets by using the numerical simulation model directly. In an exemplary experiment, the generation of a non-destructive training dataset requires almost 5 hours, which combines both the numerical analysis time and dataset reconstruction time. Further, the training of the DCGAN requires approximately 7 hours to 8 hours. After training, the generation of a new synthetic non-destructive testing dataset takes merely 30 secs by using the trained DCGAN. Thus, the required time is reduced by a factor of N/n, wherein N is the time required for creating a single NDE/NDT dataset, and n is the time required for AI-generated NDE/NDT single dataset for different NDT techniques such as Radiography, Ultrasonics, Liquid Particle, Magnetic Particle, and Infrared Imaging Therefore, the DCGAN generated synthetic non-destructive testing dataset is significantly faster than the non-destructive testing dataset reconstructed via physics based numerical analysis, thereby reducing computational resources and saving time.

In one embodiment, the dataset generation module (122) receives a random number input vector from an operator via a user interface. Upon receiving the random number input vector, the dataset generation module (122) feeds the received random number input vector to the trained DCGAN. The random number input vector can be represented as a latent space vector, wherein the latent space is simply a representation of compressed data in which similar data points are closer together in space. The latent space is useful for learning data features and for finding simpler representations of data for analysis. The trained DCGAN further generates a synthetic non-destructive testing dataset as output based on the imparted training by using the one or more non-destructive training datasets. The dataset generation module (122) receives a plurality of random number input vectors and iteratively feeds each of the received plurality of random number input vectors to the trained DCGAN so as to generate a plurality of synthetic non-destructive testing datasets as output from the trained DCGAN.

Further, the plurality of synthetic non-destructive testing datasets and the plurality of non-destructive training datasets can be fed to an Automated Defect Recognition (ADR) system. The ADR system is a computer-based defect recognition system for automatic detection of defects in physical samples, wherein the ADR system includes an inspection knowledge base that enables automated defect inspections based upon a variety of non-destructive testing datasets, particular samples under test, particular zone and region of the sample, and the types of non-destructive testing datasets used. The ADR system is built by training a Convolutional Neural Network (CNN) based Artificial Intelligence (AI) model, wherein such training process is performed by using the received plurality of synthetic non-destructive testing datasets and the plurality of non-destructive training datasets. Upon successfully training the ADR system, the trained ADR system receives one or more images of a physical sample with one or more defects in order to detect and classify the defects within the physical sample in real time. The ADR system can also be configured to represent the classified defects with bounding boxes and appropriate labels for easy interpretation by respective operator of the ADR system.

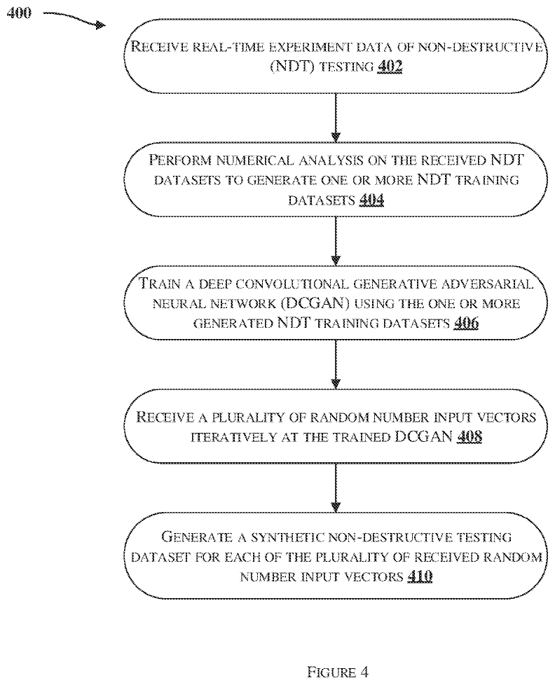

FIG. 4 illustrates a dataflow showing a method for generating NDT datasets in accordance with some embodiments of the present disclosure.

As illustrated in FIG. 4, the method (400) comprises one or more blocks implemented by the processor (112) to generate the plurality of non-destructive testing datasets by using NDGS (102). The method (400) may be described in the general context of computer executable instructions. Generally, computer executable instructions can include routines, programs, objects, components, data structures, procedures, modules, and functions, which perform specific functions or implement specific abstract data types.

The order in which the method (400) is described is not intended to be construed as a limitation, and any number of the described method blocks can be combined in any order to implement the method (400). Additionally, individual blocks may be deleted from the method (400) without departing from the spirit and scope of the subject matter described herein. Furthermore, the method (400) can be implemented in any suitable hardware, software, firmware, or combination thereof.

At block (402), real-time experimentation data of non-destructive testing is received. In one embodiment, the data acquisition module (116) receives one or more non-destructive testing datasets related to the real-time experiment of non-destructive testing of one or more physical samples from the experimentation database (104), wherein the experimentation database (104) stores the testing datasets with respect to the real-time non-destructive testing of physical samples as received from one or more systems conducting such experiment over the time. The received non-destructive testing dataset contains a variety of information with respect to the non-destructive testing of the one or more physical samples. The information related to such non-destructive testing includes but is not limited to dimensions of defective samples, expected defect morphologies, defect probabilities, the sensitivity of instruments, observation from experimental datasets, noise from instrumentation, etc. Further, the information related to one or more samples used in real-time experiments includes length, thickness, defect information, etc., related to the one or more physical samples. The information related to the real-time experimentation of non-destructive testing can also include material property, a plurality of flaw geometry features, nature of occurring locations of such flaw within the one or more physical samples, etc.

At block (404), numerical analysis is performed on the received non-destructive testing dataset. In one embodiment, the numerical analysis module (118) retrieves geometrical information of one or more representative defective samples such as geometrical dimension, flaw information, material property, etc., from the experimentation data (208). The numerical analysis module (118) determines a plurality of CAD datasets by inducing one or more flaw patterns into the determined CAD model that represents one or more actual physical defective samples. The numerical analysis module (118) further reconstructs a non-destructive training dataset for each of the CAD datasets based on the physics based numerical analysis. Thus, the numerical analysis module (118) generates a count of non-destructive training datasets similar to the count of the plurality of CAD datasets. The numerical analysis module (118) further stores the generated non-destructive training datasets as the training data (214) in the NDT database (108).

At block (406), a deep convolutional generative adversarial network (DCGAN) is trained. In one embodiment, the training module (120) retrieves the non-destructive training datasets as stored in the training data (214) and iteratively feeds each of the non-destructive training datasets to the DCGAN in order to train the DCGAN with a variety of input datasets having different types of flaws. The DCGAN explicitly uses convolutional and convolutional-transpose layers in the discriminator and generator, respectively. The generator aims to generate a synthetic non-destructive testing dataset close to the non-destructive testing dataset of the real-time experiments by fooling the discriminator. The discriminator seeks to discriminate between the synthetic non-destructive testing dataset and the non-destructive testing dataset of real-time experiments.

At block (408), a plurality of random number input vectors is received iteratively at the trained DCGAN. In one embodiment, the dataset generation module (122) receives a random number input vector from an operator via a user interface. Upon receiving the random number input vector, the dataset generation module (122) feeds the received random number input vector to the trained DCGAN. The random number input vector can be represented as a latent space vector, wherein the latent space is simply a representation of compressed data in which similar data points are closer together in space. The latent space is useful for learning data features and for finding simpler representations of data for analysis. The trained DCGAN further generates a synthetic non-destructive testing dataset as output based on the imparted training by using the one or more non-destructive training datasets.

At block (410), synthetic non-destructive testing datasets are generated. In one embodiment, the dataset generation module (122) receives a plurality of random number input vectors and iteratively feeds each of the received plurality of random number input vectors to the trained DCGAN so as to generate the plurality of synthetic non-destructive testing datasets as output from the trained DCGAN.

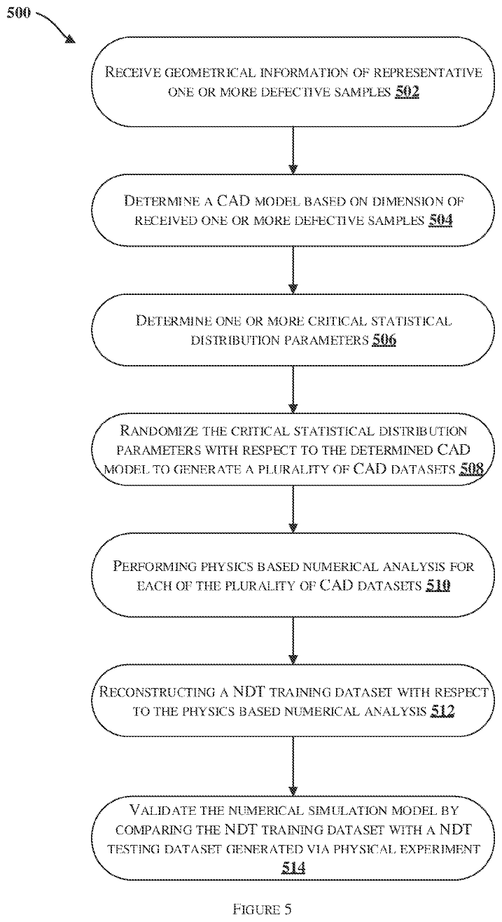

FIG. 5 illustrates a flowchart showing a method of determining a numerical simulation model for generating NDT datasets in accordance with some embodiments of the present disclosure.

As illustrated in FIG. 5, the method (500) comprises one or more blocks implemented by the processor (112) to determine the numerical simulation model for generating non-destructive testing datasets. The order in which the method (500) is described is not intended to be construed as a limitation, and any number of the described method blocks can be combined in any order to implement the method (500). Additionally, individual blocks may be deleted from the method (500) without departing from the spirit and scope of the subject matter described herein. Furthermore, the method (500) can be implemented in any suitable hardware, software, firmware, or combination thereof.

At block (502), geometrical information of representative one or more defective samples is received. In one embodiment, the data acquisition module (116) receives one or more non-destructive testing datasets related to real-time experiments of non-destructive testing of one or more defective physical samples from the experimentation database (104). The received non-destructive testing dataset contains a variety of information with respect to the non-destructive testing of the one or more physical samples. The information related to such non-destructive testing includes but is not limited to dimensions of defective samples, expected defect morphologies, defect probabilities, the sensitivity of instruments, observation from experimental datasets, noise from instrumentation, etc. Further, the information related to one or more samples used in real-time experiments includes length, thickness, defect information, etc., related to the one or more physical samples. The information related to the real-time experimentation of non-destructive testing can also include material property, a plurality of flaw geometry features, nature of occurring locations of such flaw within the one or more physical samples, etc.

At block (504), a CAD model is determined based on the dimension of received one or more defective samples. In one embodiment, the numerical analysis module (118) retrieves geometrical information of one or more representative defective samples such as geometrical dimension, flaw information, material property, etc., from the experimentation data (208) as stored by the data acquisition module (116). The numerical analysis module (118) determines a CAD model representing one or more actual physical defective samples based on the retrieved geometrical information.

At block (506), one or more critical statistical distribution parameters are determined. In one embodiment, upon determining the CAD model, the numerical analysis module (118) determines one or more critical statistical distribution parameters using probability distribution function (PDF) on plurality of factors influencing the real-time experiment such as expected defect morphologies, defect probabilities, the sensitivity of instruments etc. The PDF is a mathematical method that determines probabilities of different possible outcomes for an experiment. In an example, the critical statistical distribution parameters can include but not limited to flaw shape, flaw size, flaw orientation etc. The numerical analysis module (118) stores the one or more critical statistical distribution parameters as PDF data (210) in the NDT database (108).

At block (508), critical statistical distribution parameters are randomized with respect the determined CAD model. In one embodiment, the numerical analysis module (118) further randomizes the critical statistical distribution parameters in order to generate a plurality of artificial flaw patterns. The numerical analysis module (118) determines a plurality of CAD datasets by inducing one or more flaw patterns into the determined CAD model. Therefore, the different CAD datasets with artificial flow pattern represent different scenarios of possible defects in the physical samples.

At block (510), physics based numerical analysis is performed for CAD datasets. In one embodiment, the numerical analysis module (118) performs physics based numerical analysis for each of the determined CAD datasets by using one of Finite Element Analysis (FEA), Finite Difference Method (FDM), Finite Volume Method (FVM), etc. In an example, FEA can be used to determine the numerical simulation model, wherein the numerical simulation model can be a Finite Element (FE) simulation model. In order to perform the FEA, a Finite Element Method (FEM) is adapted, wherein the FEM is used for numerically solving differential equations arising in engineering and mathematical modeling.

At block (512), non-destructive training dataset is reconstructed with respect to physics based numerical analysis. In one embodiment, the numerical analysis module (118) reconstructs a non-destructive training dataset for each of the CAD datasets based on the physics based numerical analysis. The reconstructed non-destructive training datasets are also contained with different types of flaws that are induced during the preparation of the plurality of CAD datasets.

At block (514), the numerical simulation model is validated. In one embodiment, the numerical analysis module (118) further communicates with the experimentation system (106) in order to retrieve a non-destructive training dataset, wherein the experimentation system (106) obtains the non-destructive testing dataset by performing physical experiments of the physical sample having similar kind of defect as induced into the particular CAD dataset. Upon retrieving the non-destructive testing dataset, the numerical analysis module (118) compares the reconstructed non-destructive training dataset with the retrieved non-destructive testing dataset for verifying a desired result. In case the desired result is not achieved, the numerical analysis module (118) modifies the numerical simulation model by tweaking one or more boundary conditions and respective techniques for physics based numerical analysis until the desired results are obtained. The numerical analysis module (118) further stores information related to CAD model, the CAD datasets, information of the validated numerical simulation model as the numerical analysis data (212) in the NDT database (108).

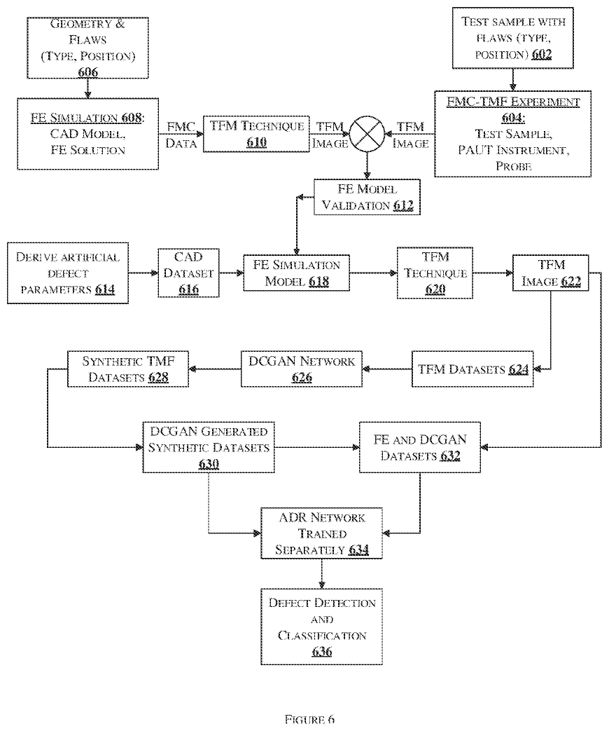

FIG. 6 illustrates an exemplary illustration of data flow for automated defect recognition in accordance with an embodiment of the present disclosure.

As illustrated in FIG. 6, different phases of data flow for automated defect recognition by using a specific numerical analysis model are described. In the example, a Finite Element (FE) simulation model is used as the numerical analysis model.

At block (602 and 604), the representative defective samples, i.e., weld samples, are manufactured in the laboratory, and the FMC-TFM experiments are conducted on the representative defective samples to generate TFM images.

At block (606, 608, and 610), geometrical information of the defective samples is used to develop the CAD model, and the Finite Element (FE) simulation is conducted on each CAD dataset generated based on the CAD model for creating Full Matrix Capture (FMC) data. The Total Focusing Method (TFM) is implemented on FMC data to generate a TFM image.

At block (612), the FE simulation based TFM images are compared with experimentally obtained TFM images in order to validate the FE simulation model. The FE simulation model boundary conditions and the respective TFM technique are reverified until the desired results are obtained.

At block (614, 616, 618, 620, and 622), a plurality of artificial weld defect parameters (AWDP) is derived using the probability density function (PDF). The AWDP for each defect is used to generate a separate CAD dataset followed by FE simulation on each of the CAD datasets to create the weld TFM dataset. The weld TFM datasets are created by applying the TFM technique on respective FMC created in the FE simulation.

At block (624, 626, and 628), the DCGAN is trained by using the limited FE simulation-based weld TFM datasets as training data to obtain a trained DCGAN. Further, a large volume of synthetic weld TFM images are generated by the trained DCGAN based on respective input from an operator.

At block (630, 632, 634, and 636), the DCGAN generated synthetic TFM datasets, and a combination of FE simulation based TFM datasets and DCGAN generated synthetic TFM datasets are used for training a deep convolutional neural network (CNN) to build the Automated Defect Recognition (ADR) system for qualifying the weldments. A mean average precision (mAP) and average loss values are calculated during training the ADR model to check the training dataset object retravel. The trained ADR system is then validated using a set of testing datasets for defect detection and classification accuracy on weld defects.

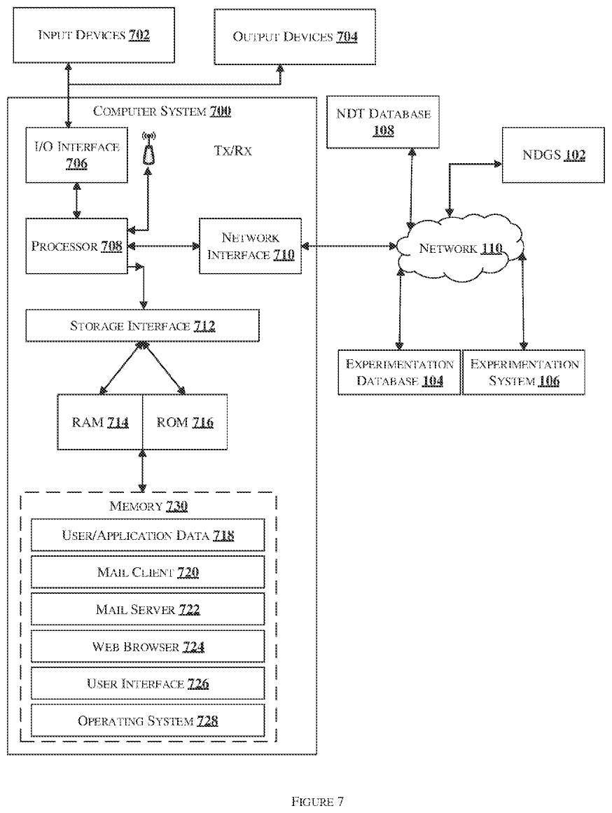

FIG. 7 illustrates a block diagram of an exemplary computer system for implementing embodiments consistent with the present disclosure.

In an embodiment, the computer system (700) may be a system for generating NDT datasets (102), which is used for improving risk assessment by providing external data. The computer system (700) may include a central processing unit (“CPU” or “processor”) (708). The processor (708) may comprise at least one data processor for executing program components for executing user or system-generated business processes. The processor (708) may include specialized processing units such as integrated system (bus) controllers, memory management control units, floating point units, graphics processing units, digital signal processing units, etc.

The processor (708) may be disposed in communication with one or more input/output (I/O) devices (702 and 704) via I/O interface (706). The I/O interface (706) may employ communication protocols/methods such as, without limitation, audio, analog, digital, stereo, IEEE-1394, serial bus, Universal Serial Bus (USB), infrared, PS/2, BNC, coaxial, component, composite, Digital Visual Interface (DVI), high-definition multimedia interface (HDMI), Radio Frequency (RF) antennas, S-Video, Video Graphics Array (VGA), IEEE 802.n/b/g/n/x, Bluetooth, cellular (e.g., Code-Division Multiple Access (CDMA), High-Speed Packet Access (HSPA+), Global System For Mobile Communications (GSM), Long-Term Evolution (LTE) or the like), etc.

Using the I/O interface (706), the computer system (700) may communicate with one or more I/O devices (702 and 704). In some implementations, the processor (708) may be disposed in communication with a communication network (110) via a network interface (710). The network interface (710) may employ connection protocols including, without limitation, direct connect, Ethernet (e.g., twisted pair 10/100/1000 Base T), Transmission Control Protocol/Internet Protocol (TCP/IP), token ring, IEEE 802.11a/b/g/n/x, etc. Using the network interface (710) and the communication network (110), the computer system (700) may be connected to the experimentation database (104), the experimentation system (106), and the NDT database (108), and the NDGS (102).

The communication network (110) can be implemented as one of the several types of networks, such as an intranet or any such wireless network interfaces. The communication network (110) may either be a dedicated network or a shared network, which represents an association of several types of networks that use a variety of protocols, for example, Hypertext Transfer Protocol (HTTP), Transmission Control Protocol/Internet Protocol (TCP/IP), Wireless Application Protocol (WAP), etc., to communicate with each other. Further, the communication network (110) may include a variety of network devices, including routers, bridges, servers, computing devices, storage devices, etc.

In some embodiments, the processor (708) may be disposed in communication with a memory (730), e.g., RAM (714), and ROM (716), etc., as shown in FIG. 7, via a storage interface (712). The storage interface (712) may connect to memory (730) including, without limitation, memory drives, removable disc drives, etc., employing connection protocols such as Serial Advanced Technology Attachment (SATA), Integrated Drive Electronics (IDE), IEEE-1394, Universal Serial Bus (USB), fiber channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory (730) may store a collection of program or database components, including, without limitation, user/application, an operating system (728), a web browser (724), a mail client (720), a mail server (722), a user interface (726), and the like. In some embodiments, the computer system (700) may store user/application data (718), such as the data, variables, records, etc., as described in this invention. Such databases may be implemented as fault-tolerant, relational, scalable, secure databases such as Oracle or Sybase.

The operating system (728) may facilitate resource management and operation of the computer system (700). Examples of operating systems include, without limitation, Apple Macintosh™ OS X™, UNIX™, Unix-like system distributions (e.g., Berkeley Software Distribution (BSD), FreeBSD™, Net BSD™, Open BSD™, etc.), Linux distributions (e.g., Red Hat™, Ubuntu™, K-Ubuntu™, etc.), International Business Machines (IBM™) OS/2™, Microsoft Windows™ (XP™, Vista/7/8, etc.), Apple iOS™, Google Android™, Blackberry™ Operating System (OS), or the like. A user interface may facilitate display, execution, interaction, manipulation, or operation of program components through textual or graphical facilities. For example, user interfaces may provide computer interaction interface elements on a display system operatively connected to the computer system (700), such as cursors, icons, checkboxes, menus, windows, widgets, etc. Graphical User Interfaces (GUIs) may be employed, including, without limitation, Apple™ Macintosh™ operating systems' Aqua™, IBM™ OS/2™, Microsoft™ Windows™ (e.g., Aero, Metro, etc.), Unix X-Windows™, web interface libraries (e.g., ActiveX, Java, JavaScript, AJAX, HTML, Adobe Flash, etc.), or the like.

The instant invention provides the technical solution to the technical problem of the existing non-destructing testing method by integrating the artificial intelligence (AI) automation system for generating a large volume of non-destructive testing datasets. The proposed system aids in generating such a large volume of synthetic non-destructive testing datasets from a much smaller NDT/NDE domain specific combination of numerical simulation and experimentally obtained datasets. The system reduces computational resources and time by a factor of N/n, wherein N is the time required for creating a single NDE/NDT dataset, and n is the time required for AI-generated NDE/NDT single dataset for different NDT techniques such as Radiography, Ultrasonics, Liquid Particle, Magnetic Particle, and Infrared Imaging. The system further enables an ADR system to provide a reliable and efficient decision to detect and classify defects by providing the ADR system large volume of synthetic non-destructive testing datasets. Therefore, the instant invention system provides an automated, robust, highly scalable, time-efficient platform to generate a large volume of synthetic non-destructive testing datasets.

The illustrated steps are set out to explain the exemplary embodiments shown, and it should be anticipated that ongoing technological development will change the manner in which particular functions are performed. These examples are presented herein for purposes of illustration and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open ended in that an item or items following any one of these words is not meant to be an exhaustive listing of such item or items or meant to be limited to only the listed item or items. It must also be noted that as used herein and in the appended claims, the singular forms “a,” “an,” and “the” include plural references unless the context clearly dictates otherwise.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., are non-transitory. Examples include random access memory (RAM), read-only memory (ROM), volatile memory, non-volatile memory, hard drives, CD ROMs, DVDs, flash drives, disks, and any other known physical storage media.

Finally, the language used in the specification has been principally selected for readability and instructional purposes, and it may not have been selected to delineate or circumscribe the inventive subject matter. Accordingly, the disclosure of the embodiments of the disclosure is intended to be illustrative, but not limiting, of the scope of the disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

1. A method of generating synthetic non-destructive testing dataset, the method comprising:
receiving one or more non-destructive testing datasets related to real-time experimentation of non-destructive testing, wherein the testing datasets include dimensions of defective samples, expected defect morphologies, defect probabilities, the sensitivity of instruments, observation from experimental datasets, noise from instrumentation;
performing numerical analysis on the received one or more non-destructive testing datasets for generating one or more non-destructive training datasets by using a numerical simulation model, wherein each of the non-destructive testing datasets contains one or more flawed geometrical features;
training a Deep Convolutional Generative Adversarial Network (DCGAN) by using the generated one or more non-destructive training datasets with flaw geometrical features;
receiving a plurality of random number input vectors iteratively at the trained DCGAN; and
generating, by the trained DCGAN, a synthetic non-destructive testing dataset for each of the plurality of received random number input vectors.

2. The method as claimed in claim 1, wherein the numerical simulation model is determined by using one of numerical methods such as Finite Element Analysis (FEA), Finite Difference Method (FDM), Finite Volume Method.

3. The method as claimed in claim 1, wherein the numerical simulation model is determined by steps of:
receiving geometrical information of representative one or more defective samples, wherein the geometrical information includes geometrical dimension, flaw information, material property of the one or more defective samples;
determining a CAD (computer aided design) model representing actual defective samples based on dimension of one or more defective samples;
determining one or more critical statistical distribution parameters, wherein the one or more critical statistical parameters are obtained based on flaw geometry features and nature of occurring locations of such flaw of the one or more defective samples by using probability distribution function (PDF);
randomizing the critical statistical distribution parameters with respect to the determined CAD model for generating a plurality of CAD datasets;
performing physics based numerical analysis for each of the plurality of CAD datasets by using one of numerical methods such as Finite Element Analysis (FEA), Finite Difference Method (FDM), Finite Volume Method (FVM);
reconstructing a non-destructive training dataset with respect to the physics based numerical analysis; and
validating the numerical simulation model by comparing the reconstructed non-destructive training dataset with a non-destructive testing dataset obtained from physical experimentation of one of the one or more defective samples.

4. The method as claimed in claim 3, wherein randomizing of the critical statistical parameters is performed based on flaw parameters like flaw shape, flaw size, flaw orientation, and material properties.

5. The method as claimed in claim 1, wherein the training of the DCGAN comprises:
receiving, by the DCGAN, each of the generated non-destructive training dataset as input in an iterative manner;
generating, by a generator model of the DCGAN, one or more datasets similar to the input non-destructive training dataset in each iteration by incorporating feedback from a discriminator model of the DCGAN;
discriminating, by the discriminator model of the DCGAN, the generated one or more datasets as fake or original with respect to the input non-destructive training dataset in each iteration and backpropagating respective output to the generator model of the DCGAN, wherein such backpropagation optimizes one or more hyper-parameters that determines the DCGAN structure.

6. A system for generating synthetic non-destructive testing dataset, the system comprising:
a processor; and
a memory communicatively coupled with the processor, wherein the memory stores processor-executable instructions, which on execution, cause the processor to:
receive one or more non-destructive testing datasets related to real-time experimentation of non-destructive testing, wherein the testing datasets include dimensions of defective samples, expected defect morphologies, defect probabilities, the sensitivity of instruments, observation from experimental datasets, noise from instrumentation;
perform numerical analysis on the received one or more non-destructive testing datasets for generating one or more non-destructive training datasets by using a numerical simulation model, wherein each of the non-destructive testing datasets contains one or more flawed geometrical features;
train a Deep Convolutional Generative Adversarial Network (DCGAN) by using the generated one or more non-destructive training datasets with flaw geometrical features;
receive a plurality of random number input vectors iteratively at the trained DCGAN; and
generate a synthetic non-destructive testing dataset for each of the plurality of received random number input vectors using the trained DCGAN.

7. The system as claimed in claim 6, wherein the numerical simulation model is determined by using one of numerical methods such as Finite Element Analysis (FEA), Finite Difference Method (FDM), Finite Volume Method.

8. The system as claimed in claim 6, wherein the processor is configured to determine the numerical simulation model, by:
receiving geometrical information of representative one or more defective samples, wherein the geometrical information includes geometrical dimension, flaw information, material property of the one or more defective samples;
determining a CAD (computer aided design) model representing actual defective samples based on dimension of one or more defective samples;
determining one or more critical statistical distribution parameters, wherein the one or more critical statistical parameters are obtained based on flaw geometry features and nature of occurring locations of such flaw of the one or more defective samples by using probability distribution function (PDF);
randomizing the critical statistical distribution parameters with respect to the determined CAD model for generating a plurality of CAD datasets;
performing physics based numerical analysis for each of the plurality of CAD datasets by using one of numerical methods such as Finite Element Analysis (FEA), Finite Difference Method (FDM), Finite Volume Method (FVM);
reconstructing a non-destructive training dataset with respect to the physics based numerical analysis; and
validating the numerical simulation model by comparing the reconstructed non-destructive training dataset with a non-destructive testing dataset obtained from physical experimentation of one of the one or more defective samples.

9. The system as claimed in claim 6, wherein randomizing of the critical statistical parameters is performed based on flaw parameters like flaw shape, flaw size, flaw orientation, and material properties.

10. The system as claimed in claim 6, wherein the processor is configured to train the DCGAN, by:
receiving, by the DCGAN, each of the generated non-destructive training dataset as input in an iterative manner;
generating, by a generator model of the DCGAN, one or more datasets similar to the input non-destructive training dataset in each iteration by incorporating feedback from a discriminator model of the DCGAN;
discriminating, by the discriminator model of the DCGAN, the generated one or more datasets as fake or original with respect to the input non-destructive training dataset in each iteration and backpropagating respective output to the generator model of the DCGAN, wherein such backpropagation optimizes one or more hyper-parameters that determines the DCGAN structure.

1. A method of generating synthetic non-destructive testing dataset, the method comprising:
receiving one or more non-destructive testing datasets related to real-time experimentation of non-destructive testing, wherein the testing datasets include dimensions of defective samples, expected defect morphologies, defect probabilities, the sensitivity of instruments, observation from experimental datasets, noise from instrumentation;
performing numerical analysis on the received one or more non-destructive testing datasets for generating one or more non-destructive training datasets by using a numerical simulation model, wherein each of the non-destructive testing datasets contains one or more flawed geometrical features;
training a Deep Convolutional Generative Adversarial Network (DCGAN) by using the generated one or more non-destructive training datasets with flaw geometrical features;
receiving a plurality of random number input vectors iteratively at the trained DCGAN; and
generating, by the trained DCGAN, a synthetic non-destructive testing dataset for each of the plurality of received random number input vectors.

2. The method as claimed in claim 1, wherein the numerical simulation model is determined by using one of numerical methods such as Finite Element Analysis (FEA), Finite Difference Method (FDM), Finite Volume Method.

3. The method as claimed in claim 1, wherein the numerical simulation model is determined by steps of:
receiving geometrical information of representative one or more defective samples, wherein the geometrical information includes geometrical dimension, flaw information, material property of the one or more defective samples;
determining a CAD (computer aided design) model representing actual defective samples based on dimension of one or more defective samples;
determining one or more critical statistical distribution parameters, wherein the one or more critical statistical parameters are obtained based on flaw geometry features and nature of occurring locations of such flaw of the one or more defective samples by using probability distribution function (PDF);
randomizing the critical statistical distribution parameters with respect to the determined CAD model for generating a plurality of CAD datasets;
performing physics based numerical analysis for each of the plurality of CAD datasets by using one of numerical methods such as Finite Element Analysis (FEA), Finite Difference Method (FDM), Finite Volume Method (FVM);
reconstructing a non-destructive training dataset with respect to the physics based numerical analysis; and
validating the numerical simulation model by comparing the reconstructed non-destructive training dataset with a non-destructive testing dataset obtained from physical experimentation of one of the one or more defective samples.

4. The method as claimed in claim 3, wherein randomizing of the critical statistical parameters is performed based on flaw parameters like flaw shape, flaw size, flaw orientation, and material properties.

5. The method as claimed in claim 1, wherein the training of the DCGAN comprises:
receiving, by the DCGAN, each of the generated non-destructive training dataset as input in an iterative manner;
generating, by a generator model of the DCGAN, one or more datasets similar to the input non-destructive training dataset in each iteration by incorporating feedback from a discriminator model of the DCGAN;
discriminating, by the discriminator model of the DCGAN, the generated one or more datasets as fake or original with respect to the input non-destructive training dataset in each iteration and backpropagating respective output to the generator model of the DCGAN, wherein such backpropagation optimizes one or more hyper-parameters that determines the DCGAN structure.

6. A system for generating synthetic non-destructive testing dataset, the system comprising:
a processor (112); and
a memory (114) communicatively coupled with the processor (112), wherein the memory stores processor-executable instructions, which on execution, cause the processor (112) to:
receive one or more non-destructive testing datasets related to real-time experimentation of non-destructive testing, wherein the testing datasets include dimensions of defective samples, expected defect morphologies, defect probabilities, the sensitivity of instruments, observation from experimental datasets, noise from instrumentation;
perform numerical analysis on the received one or more non-destructive testing datasets for generating one or more non-destructive training datasets by using a numerical simulation model, wherein each of the non-destructive testing datasets contains one or more flawed geometrical features;
train a Deep Convolutional Generative Adversarial Network (DCGAN) by using the generated one or more non-destructive training datasets with flaw geometrical features;
receive a plurality of random number input vectors iteratively at the trained DCGAN; and
generate a synthetic non-destructive testing dataset for each of the plurality of received random number input vectors using the trained DCGAN.

7. The system as claimed in claim 6, wherein the numerical simulation model is determined by using one of numerical methods such as Finite Element Analysis (FEA), Finite Difference Method (FDM), Finite Volume Method.

8. The system as claimed in claim 6, wherein the processor (112) is configured to determine the numerical simulation model, by:
receiving geometrical information of representative one or more defective samples, wherein the geometrical information includes geometrical dimension, flaw information, material property of the one or more defective samples;
determining a CAD (computer aided design) model representing actual defective samples based on dimension of one or more defective samples;
determining one or more critical statistical distribution parameters, wherein the one or more critical statistical parameters are obtained based on flaw geometry features and nature of occurring locations of such flaw of the one or more defective samples by using probability distribution function (PDF);
randomizing the critical statistical distribution parameters with respect to the determined CAD model for generating a plurality of CAD datasets;
performing physics based numerical analysis for each of the plurality of CAD datasets by using one of numerical methods such as Finite Element Analysis (FEA), Finite Difference Method (FDM), Finite Volume Method (FVM);
reconstructing a non-destructive training dataset with respect to the physics based numerical analysis; and
validating the numerical simulation model by comparing the reconstructed non-destructive training dataset with a non-destructive testing dataset obtained from physical experimentation of one of the one or more defective samples.

9. The system as claimed in claim 6, wherein randomizing of the critical statistical parameters is performed based on flaw parameters like flaw shape, flaw size, flaw orientation, and material properties.

10. The system as claimed in claim 6, wherein the processor (112) is configured to train the DCGAN, by:
receiving, by the DCGAN, each of the generated non-destructive training dataset as input in an iterative manner;
generating, by a generator model of the DCGAN, one or more datasets similar to the input non-destructive training dataset in each iteration by incorporating feedback from a discriminator model of the DCGAN;
discriminating, by the discriminator model of the DCGAN, the generated one or more datasets as fake or original with respect to the input non-destructive training dataset in each iteration and backpropagating respective output to the generator model of the DCGAN, wherein such backpropagation optimizes one or more hyper-parameters that determines the DCGAN structure.
